(19) United States
(12) Patent Application Publication
(10) Pub. No.: US 2023/0392250 A1
(43) Pub. Date: Dec. 7, 2023

(54) DEPOSITION DEVICE AND MANUFACTURING METHOD FOR DISPLAY DEVICE BY USING THE SAME

(71) Applicant: Samsung Display Co., LTD., Yongin-si (KR)

(72) Inventor: Young Min MOON, Yongin-si (KR)

(73) Assignee: Samsung Display Co., LTD., Yongin-si (KR)

(21) Appl. No.: 18/328,167

(22) Filed: Jun. 2, 2023

(30) Foreign Application Priority Data
Jun. 3, 2022 (KR) 10-2022-0068255

(51) Int. Cl. C23C 14/04; H10K 71/16

(52) U.S. Cl. CPC C23C 14/042; H10K 71/166

(57) ABSTRACT

A deposition device may include a substrate supporter that supports a substrate; a source supply part that supplies a deposition material to the substrate; a deposition mask positioned between the substrate and the source supply part; and a light supply part that is detachably disposed or detachable to face the substrate via the deposition mask between the substrate and the light supply part.

### CROSS-REFERENCE TO RELATED APPLICATION

This application claims priority to and benefits of Korean Patent Application No. 10-2022-0068255 under 35 U.S.C. § 119, filed in the Korean Intellectual Property Office on Jun. 3, 2022, the entire contents of which are incorporated herein by reference.

### BACKGROUND

### 1. Technical Field

The disclosure relates to a deposition device and a manufacturing method of a display device using the same.

### 2. Description of the Related Art

Display device implementations may include a liquid crystal display (LCD), a plasma display panel (PDP), an organic light emitting diode (OLED) device, a field emission display (FED), and/or an electrophoretic display device.

In a case of forming the display device, required organic layers may be stacked on multiple pixel areas.

As the resolution of the display device increases, a gap between a region where a material for a first deposition is deposited and a region where a material for a second deposition is deposited becomes narrower, and as a result of the narrower gap, the material for the first deposition that emits a first color and the material for the second deposition that emits a second color are mixed, and an error in which the first color and the second color are mixed may occur more frequently due to the insufficient isolation caused by the narrower gap.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein

### SUMMARY

Embodiments provide a deposition device configured to prevent unnecessary deposition of a material in a peripheral area and a manufacturing method of a display device using the same.

However, tasks to be solved by embodiments need not be limited to the above-described task, and may be extended in various ways within a range of technical scopes included in the embodiments.

A deposition device according to an embodiment may include: a substrate supporter that supports a substrate; a source supply part that supplies a deposition material to the substrate; a deposition mask positioned between the substrate and the source supply part; and a light supply part that is detachably disposed to face the substrate via the deposition mask between the substrate and the light supply part.

The source supply part may supply an organic material, and the light supply part may supply a light that is ultraviolet rays.

The light may have a wavelength of about 160 nm to about 172 nm, and the light may have energy of about 7.21 eV to about 7.75 eV.

Chemical bonds of a selected portion of the organic material may be dissociated by the light.

The deposition mask may include a blocking part and a deposition part, the blocking part may include a metal, and the deposition part may include a fine metal pattern.

The deposition mask may include a blocking part and a deposition part, and the deposition mask may include an open part formed in the deposition part.

A manufacturing method of a display device according to an embodiment includes: mounting a substrate on a substrate supporter; disposing a first mask to be adjacent to the substrate; depositing a first organic material on the substrate from a source supply part through the first mask; disposing a second mask to be adjacent to the substrate; disposing a light supply part to face the substrate with the second mask disposed between the light supply part and the substrate; and causing removal of a selected portion of the first organic material based on supplying a light from the light supply part to the substrate through the second mask.

The manufacturing method of the display device may further include, before the depositing of the first organic material, disposing the light supply part to face the substrate via the first mask, and supplying the light to the first mask and the substrate from the light supply part.

The manufacturing method of the display device may further include, after the supplying of the light, detaching the light supply part.

The first mask may include a first blocking part and a first deposition part, the first blocking part may include a metal, and the first deposition part may include a fine metal pattern.

The first organic material may be deposited in a deposition region corresponding to the first deposition part of the first mask among the substrate region and a peripheral area surrounding the deposition region.

The second mask may include a second blocking part and a second deposition part, the second blocking part may include a metal, and the second deposition part may include a fine metal pattern.

A portion of the second deposition part may overlap the peripheral area.

The light supply part may supply the light, which is ultraviolet rays.

The light may dissociate chemical bonds of the selected portion of the first organic material deposited in the peripheral area overlapping the portion of the second deposition part.

The light supply part may supply the light having a wavelength of about 160 nm to 172 nm, and energy of about 7.21 eV to about 7.75 eV.

The manufacturing method of the display device may further include, after the detaching of the light supply part, depositing a second organic material on the substrate through the second mask from the source supply part.

The first mask may include a first blocking part and a first transmissive part, the second mask may include a second blocking part and a second transmissive part, the first mask may include a first opened part formed in the first transmissive part, and the second mask may include a second opened part formed in the second transmissive part.

The first mask and the second mask may be disposed so that the first blocking part of the first mask may overlap the second transmissive part of the second mask and the first transmissive part of the first mask may overlap the second blocking part of the second mask.

The first organic material may be deposited in a deposition region corresponding to the transmissive part of the first mask among the substrate region and a peripheral area of the deposition region, and the peripheral area of the deposition region may overlap the second transmissive part of the second mask.

The light may dissociate chemical bonds of the selected portion of the first organic material deposited in the peripheral area of the deposition region overlapping the second transmissive part of the second mask.

According to the deposition device and the manufacturing method of the display device using the same according to the embodiment, unnecessary deposition in the peripheral area may be prevented during the deposition process, and thus process accuracy deterioration due to the unnecessary deposition may be prevented.

The effects of the embodiments are not limited to the above-described effects, and may be expanded in various ways in the range of the ideas and the areas of the embodiments.

### BRIEF DESCRIPTION OF THE DRAWINGS

The above and other aspects and features of the disclosure will become more apparent by describing in detail embodiments thereof with reference to the attached drawings, in which:

FIG. 1 is a simplified diagram of a deposition device according to an embodiment.

FIG. 2 to FIG. 6 are schematic views showing a manufacturing method of a display device using a deposition device according to an embodiment.

FIG. 7 to FIG. 9 are schematic views showing a manufacturing method of a display device using a deposition device according to another embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In order to clarify the embodiments, parts that are not directly connected with the description will be omitted, and the same elements or equivalents are referred to by the same reference numerals throughout the specification.

Further, the accompanying drawings are provided only in order to allow embodiments disclosed in the specification to be readily understood, and are not to be interpreted as limiting the spirit of the embodiments as disclosed in the specification, and it is to be understood that the embodiments include all modifications, equivalents, and substitutions without departing from the scope and spirit of the disclosure.

Further, since sizes and thicknesses of constituent members shown in the accompanying drawings are arbitrarily given for better understanding and ease of description, the embodiments are not limited to the illustrated sizes and thicknesses. In the drawings, the thickness of layers, films, panels, regions, etc., may be exaggerated for clarity. In the drawings, for better understanding and ease of description, thicknesses of some layers and areas may be excessively displayed.

It will be understood in case that an element such as a layer, film, region, or substrate is referred to as being “on” another element, it can be directly on the other element or intervening elements may also be present. In contrast, in case that an element is referred to as being “directly on” another element, there are no intervening elements present. Further, in the specification, the word “on” or “above” an object portion means positioned on or below the object portion, and does not necessarily mean positioned on the upper side of the object portion based on a gravitational direction.

For example, the spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

The term “overlap” may include layer, stack, face or facing, extending over, covering or partly covering or any other suitable term as would be appreciated and understood by those of ordinary skill in the art.

Further, in the specification, the phrase “on a plane” (or “plan view”) means when an object portion is viewed from above (or below, as appropriate), and the phrase “on a cross-section” (or “in a cross-sectional view”) means when a cross-section taken by vertically cutting an object portion is viewed from the side. A “side view” refers to a view of the object portion in a direction that is perpendicular (i.e., orthogonal) to the plan view but not a cross-section of the object portion.

The term “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

The term “and/or” includes all combinations of one or more of which associated configurations may define. For example, “A and/or B” may be understood to mean “A, B, or A and B.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, various embodiments and variations are described in detail with reference to accompanying drawings.

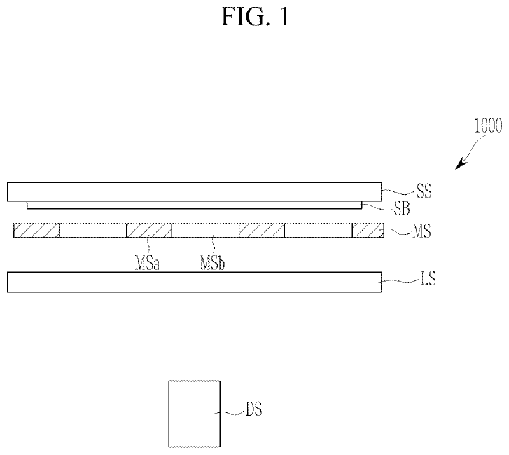

A deposition device 1000 according to an embodiment is described with reference to FIG. 1. FIG. 1 is a simplified diagram (in a side view) of a deposition device 1000 according to an embodiment.

Referring to FIG. 1, a deposition device 1000 according to an embodiment may include a substrate supporter SS that supports a substrate SB mounted on the substrate supporter SS, a source supply unit (or source supply part) DS that provides a source for a deposition process performed on the substrate SB while mounted on the substrate supporter SS, a deposition mask MS positioned between the source supply unit DS and the substrate supporter SS, and a light supply unit (or light supply part) LS positioned between the deposition mask MS and the source supply unit DS.

The deposition mask MS and the light supply unit LS may be movable into the deposition device 1000, may be disposed in (e.g., enclosed within) the deposition device 1000, and/or may be detached from the deposition device 1000 as needed.

The deposition mask MS may include a blocking part MSa through which the source supplied from the source supply unit DS cannot pass, and a deposition part MSb through which the source supplied from the source supply unit DS can pass. The deposition mask MS may be a fine metal mask (FMM) including a fine metal pattern formed on the deposition part MSb and that allows the source supplied from the source supply unit DS to pass through the fine metal pattern. As another example, the deposition mask MS may be an open mask in which the metal is not disposed on the deposition part MSb.

The source supply unit DS may supply an organic material, and the light supply unit LS may supply vacuum ultraviolet rays (VUV) but is not limited thereto. The light supplied by the light supply unit LS may have a wavelength of about 160 nm to about 172 nm, and the light may have energy of about 7.21 eV to about 7.75 eV.

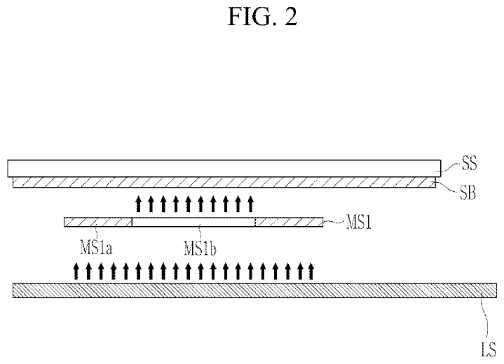

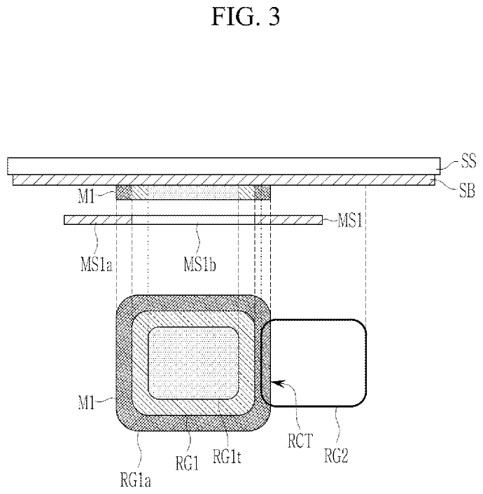

Next, a manufacturing method of the display device using the deposition device according to an embodiment is described with reference to FIG. 2 to FIG. 6 along with FIG. 1. FIG. 2 to FIG. 6 are schematic views showing a manufacturing method of a display device using a deposition device according to an embodiment. FIGS. 3 to FIG. 6 each show a side view and a corresponding plan view of an associated manufacturing operation. In FIG. 2 to FIG. 6, the substrate and the deposition mask are shown as a side view, and the planar region to be deposited is shown at a lower side in a plan view.

Referring to FIG. 2 together with FIG. 1, after the substrate SB is mounted on the substrate supporter SS and the first deposition mask MS1 is disposed adjacent to the substrate SB, the light supply unit LS is disposed to face the substrate SB via the first deposition mask MS1 in between, and then a light is supplied from the light supply unit LS to the substrate SB.

The first deposition mask MS1 may include a first blocking part MS1a and a first deposition part MS1b.

The light emitted from the light supply unit LS may be blocked in the region corresponding to the first blocking part MS1a of the first deposition mask MS1 and incident to an exposed region of the substrate SB corresponding to the first deposition part MS1b of the first deposition mask MS1 among the region of the substrate SB.

For example, the light emitted by the light supply unit LS may be vacuum ultraviolet rays (VUV). The light may have a wavelength of about 160 nm to 172 nm, and the light may have energy of about 7.21 eV to about 7.75 eV.

In this way, by supplying the light to the exposed region of the substrate SB corresponding to the first deposition part MS1b of the first deposition mask MS1 among the exposed regions of the substrate SB, foreign particles that may be positioned on the substrate SB and the first deposition mask MS1 may be removed based on the exposure to the emitted light.

Next, referring to FIG. 3 together with FIG. 1 and FIG. 2, in the state that the first deposition mask MS1 is disposed adjacent to the substrate SB, after removing the light supply unit LS, the first deposition material M1 is deposited from the source supply unit DS of FIG. 1 onto the substrate SB. For example, the first deposition material M1 may form an organic layer that may emit a first color.

As described above, the first deposition mask MS1 may include the first blocking part MS1a and the first deposition part MS1b. As illustrated in FIG. 3, the first deposition part MS1b may have a larger area than the first target region RG1t in which the first deposition material M1 is to be deposited.

In case that the first deposition material M1 is deposited on the substrate SB by using the first deposition mask MS1, the first deposition material M1 may be deposited in the first deposition region RG1 corresponding to the first deposition part MS1b and the first edge region RG1a, which is an outer region of the first deposition region RG1, for example due to a shadow effect caused by a space between the first deposition mask MS1 and the substrate SB.

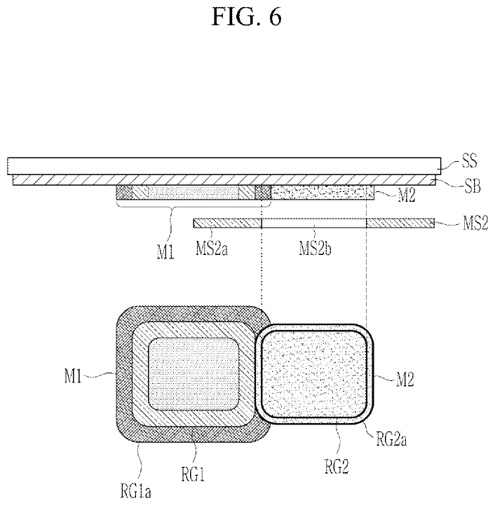

A portion of the first edge region RG1a may overlap a second deposition region RG2 in which a second deposition material (M2 of FIG. 6) will be deposited adjacent to the first target region RG1t (the overlapped regions also referred to herein as a contaminated region RCT), and, if not removed, the first deposition material M1 deposited at the contaminated region RCT in the second deposition region RG2 may be mixed with the second deposition material (M2 of FIG. 6) to be subsequently deposited. For example, the second deposition material M2 may be an organic layer emitting a different color from the first color, and the first deposition material M1 emitting the first color and the second deposition material emitting the second color could be mixed in the contaminated region RCT, so that an error in which the first color and the second color are mixed may occur.

As the resolution of the display device increases, the gap between the region where the first deposition material is deposited and the region where the second deposition material is deposited becomes narrower, whereby the first deposition material that emits the first color and the second deposition material that emits the second color are mixed, so that the error of the mixture of the first color and the second color may occur more often.

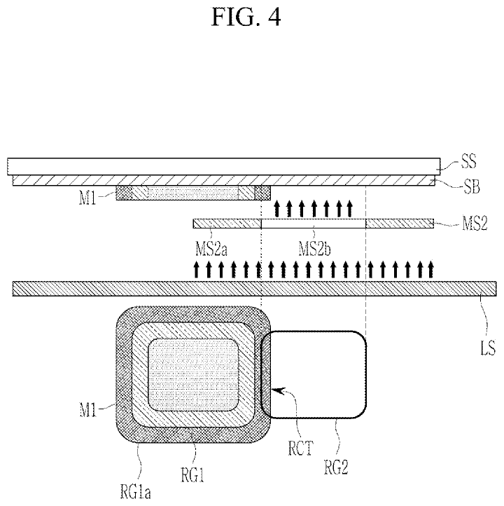

Next, referring to FIG. 4 together with FIG. 1 to FIG. 3, after the second deposition mask MS2 is disposed adjacent to the substrate SB, and then the light supply unit LS is disposed to face the substrate SB via the second deposition mask MS2 therebetween, the light from the light supply unit LS is supplied to the substrate SB. For example, the light may be vacuum ultraviolet rays (VUV). The light may have a wavelength of about 160 nm to 172 nm, and light may have energy of about 7.21 eV to about 7.75 eV.

The second deposition mask MS2 may include a second blocking part MS2a and a second deposition part MS2b overlapping the contaminated region RCT.

In this way, in case that the light is irradiated to the substrate SB by using the second deposition mask MS2, the light source may not be supplied to the region corresponding to the second blocking part MS2a of the second deposition mask MS2 of the substrate SB, and the light source may be supplied only to the region corresponding to the second deposition part of MS2b of the second deposition mask MS2 among the substrate SB overlapping the contaminated region RCT.

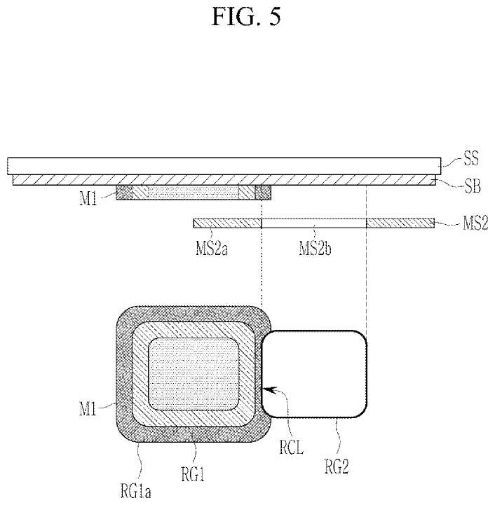

By supplying the light to the second deposition part MS2b of the second deposition mask MS2, the organic material bonds of a selected portion of the first deposition material deposited in the contaminated region RCT corresponding to the second deposition part MS2b of the second deposition mask MS2, and for example, the chemical bonds of C—C, C—O, C—H, and C═O may be dissociated, thereby, as shown in FIG. 5, causing the first deposition material M1 deposited in the region corresponding to the second deposition part MS2b of the second deposition mask MS2 to be removed, resulting in a cleaned region RCL in FIG. 5. At the same time, foreign particles attached to the second deposition mask MS2 may also be removed.

Next, referring to FIG. 6 together with FIG. 1 to FIG. 5, in the state that the second deposition mask MS2 is disposed adjacent to the substrate SB, the light supply unit LS is removed, and then the second deposition material M2 from the source supply unit DS of FIG. 1 is disposed on the substrate SB. For example, the second deposition material M2 may be an organic layer that emits a second color that is different from the first color of the first deposition material M1.

The organic layer emitting the second color may be deposited not only in the second deposition region RG2 corresponding to the second deposition part MS2b, but also in the second edge region RG2a, which is an outer region of the second deposition region RG2. The second edge region RG2a may partially overlap the region where the organic layer emitting a third color to be subsequently deposited will be deposited.

As previously explained with reference to FIG. 5, by depositing the organic layer of the second deposition material M2 that emits the second color after first removing the organic layer of the first deposition material M1 that emits the first color from the region corresponding to the second deposition part MS2b of the second deposition mask MS2 among the regions of the substrate SB (resulting in the cleaned region RCL prior to depositing the second deposition material M2), it is possible to prevent the mixing of the organic layer emitting the first color (from the first deposition material M1) and the organic layer emitting the second color (from the second deposition layer M2), which may occur at the edge of the second deposition part MS2b of the second deposition mask MS2.

Subsequently, similarly to as described with reference to FIG. 4 and FIG. 5, after removing the organic layer that emits the second color (from the second deposition layer M2) deposited on the outer part of the second deposition part MS2b of the second deposition mask MS2 by using the third deposition mask, the organic layer that emits the third color may be deposited by using the third deposition mask.

Through this, it is possible to prevent (or at least minimize) the organic layers emitting the light of different colors from being mixed in the regions adjacent to each other. If desired, additional removal of any of the first deposition material M1 and/or the second deposition material M2 may be accomplished, for example, based on applying light from the light source LS via a mask providing an exposed region overlapping an intersecting region formed by the edge region RG1 a intersecting the edge region RG2a (the mask may be implemented, for example, based on combined use of the masks MS1 and MS2).

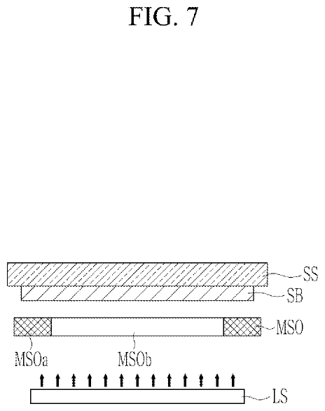

Next, the manufacturing method of the display device according to another embodiment is described with reference to FIG. 7 to FIG. 9 along with FIG. 1. FIG. 7 to FIG. 9 are schematic views showing a manufacturing method of a display device using a deposition device according to another embodiment. In FIG. 7 to FIG. 9, an embodiment of using the deposition mask on the substrate SB is shown.

Referring to FIG. 7 together with FIG. 1, after the substrate SB is mounted on the substrate supporter SS and the fourth deposition mask MSO is disposed adjacent to the substrate SB, the light supply unit LS may be disposed to face the substrate SB with the fourth deposition mask MSO in between, and then the light may be supplied from the light supply unit LS to the substrate SB.

The fourth deposition mask MSO may include a third blocking part MSOa and a third transmissive part MSOb, and the third transmissive part MSOb of the fourth deposition mask MSO may be an open mask.

The light emitted from the light supply unit LS may be blocked in the region corresponding to the third blocking part MSOa of the fourth deposition mask MSO and may enter into the region of the substrate SB corresponding to the third transmissive part MSOb of the fourth deposition mask MSO among the regions of the substrate SB.

For example, the light may be vacuum ultraviolet rays (VUV). The light may have a wavelength of about 160 nm to about 172 nm, and light may have energy of about 7.21 eV to about 7.75 eV.

In this way, by supplying the light to the region of the substrate SB corresponding to the third transmissive part MSOb of the fourth deposition mask MSO among the regions of the substrate SB, foreign particles that may be positioned on the substrate SB and the fourth deposition mask MSO may be removed.

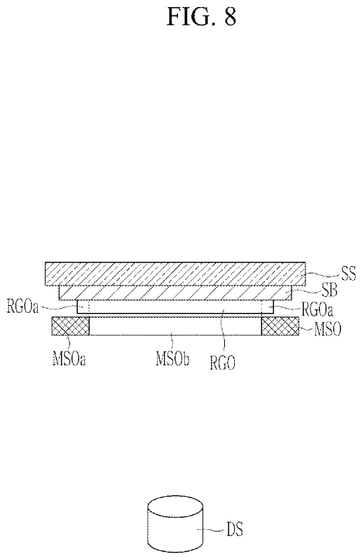

Next, referring to FIG. 8 together with FIG. 1 and FIG. 7, in the state that the fourth deposition mask MSO is disposed adjacent to the substrate SB, after removing the light supply unit LS, the deposition material from the source supply unit DS is deposited on the substrate SB. For example, the deposition material may be an organic emission layer.

When the organic emission layer is deposited on the substrate SB by using the fourth deposition mask MSO, in addition to the deposition region RGO corresponding to the third transmissive part MSOb of the fourth deposition mask MSO, the organic emission layer may also be deposited on the edge region RGOa, which is the outer region of the deposition region RGO.

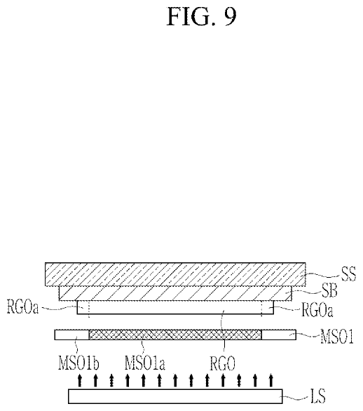

Next, referring to FIG. 9 together with FIG. 1, FIG. 7, and FIG. 8, the light blocking mask MSO1 is disposed adjacent to the substrate SB, the light supply unit LS is disposed to face the substrate SB with the light blocking mask MSO1 in between, and then the light is supplied from the light supply unit LS to the substrate SB. For example, the light may be vacuum ultraviolet rays (VUV). The light may have a wavelength of about 160 nm to about 172 nm, and light may have energy of about 7.21 eV to about 7.75 eV.

The light blocking mask MSO1 may include a fourth blocking part MSO1a and a fourth transmissive part MSO1b.

The fourth blocking part MSO1a of the light blocking mask MSO1 may correspond to the third transmissive part MSOb of the fourth deposition mask MSO, and the fourth transmissive part MSO1b of the light blocking mask MSO1 may correspond to the third blocking part MSOa of the fourth deposition mask MSO.

As such, in case that the light is irradiated to the substrate SB by using the light blocking mask MSO1, the light source may not be supplied to the region corresponding to the fourth blocking part MSO1a of the light blocking mask MSO1 among the substrate SB, and the light source may be supplied only to the region corresponding to the fourth transmissive part MSO1b of the light blocking mask MSO1 among the substrate SB.

As the light is supplied to the fourth transmissive part MSO1b of the light blocking mask MSO1, the unnecessarily deposited organic emission layer may be removed in the region corresponding to the fourth transmissive part MSO1b of the first light blocking mask MSO1, including the edge region RGOa.

As such, according to the deposition device and the manufacturing method of the display device using the same according to the embodiment, during the deposition process, the unnecessary deposited material in the peripheral area may be removed through the light supply, thereby preventing the unnecessary deposition, thereby preventing the deterioration of the process accuracy due to the unnecessary deposition.

While this disclosure has been described in connection with what is presently considered to be practical embodiments, it is to be understood that the disclosure is not limited to the disclosed embodiments. On the contrary, it is intended to cover various modifications and equivalent arrangements included within the spirit and scope of the appended claims.

What is claimed is:

1. A deposition device comprising:
a substrate supporter that supports a substrate;
a source supply part that supplies a deposition material to the substrate;
a deposition mask positioned between the substrate and the source supply part; and
a light supply part that is detachably disposed to face the substrate via the deposition mask between the substrate and the light supply part.

2. The deposition device of claim 1, wherein
the source supply part supplies an organic material, and
the light supply part supplies light that is ultraviolet rays.

3. The deposition device of claim 2, wherein
the light has a wavelength of about 160 nm to about 172 nm, and
the light has energy of about 7.21 eV to about 7.75 eV.

4. The deposition device of claim 3, wherein chemical bonds of a selected portion of the organic material are dissociated by the light.

5. The deposition device of claim 1, wherein
the deposition mask includes a blocking part and a deposition part,
the blocking part includes a metal, and
the deposition part includes a fine metal pattern.

6. The deposition device of claim 1, wherein
the deposition mask includes a blocking part and a deposition part, and
the deposition mask includes an open part formed in the deposition part.

7. A manufacturing method of a display device comprising:
mounting a substrate on a substrate supporter;
disposing a first mask to be adjacent to the substrate;
depositing a first organic material on the substrate from a source supply part through the first mask;
disposing a second mask to be adjacent to the substrate;
disposing a light supply part to face the substrate with the second mask disposed between the light supply part and the substrate; and
causing removal of a selected portion of the first organic material based on supplying light from the light supply part to the substrate through the second mask.

8. The manufacturing method of the display device of claim 7, further comprising:
before the depositing of the first organic material, disposing the light supply part to face the substrate via the first mask; and
supplying the light to the first mask and the substrate from the light supply part.

9. The manufacturing method of the display device of claim 8, further comprising:
after the supplying of the light, detaching the light supply part.

10. The manufacturing method of the display device of claim 7, wherein
the first mask includes a first blocking part and a first deposition part,
the first blocking part includes a metal, and
the first deposition part includes a fine metal pattern.

11. The manufacturing method of the display device of claim 10, wherein the first organic material is deposited in a deposition region corresponding to the first deposition part of the first mask among the substrate region and a peripheral area surrounding the deposition region.

12. The manufacturing method of the display device of claim 11, wherein
the second mask includes a second blocking part and a second deposition part,
the second blocking part includes a metal,
the second deposition part includes a fine metal pattern, and
a portion of the second deposition part overlaps the peripheral area.

13. The manufacturing method of the display device of claim 12, wherein the light supply part supplies the light which is ultraviolet rays.

14. The manufacturing method of the display device of claim 13, wherein the light dissociates chemical bonds of the selected portion of the first organic material deposited in the peripheral area overlapping the portion of the second deposition part.

15. The manufacturing method of the display device of claim 14, wherein the light supply part supplies the light having a wavelength of about 160 nm to about 172 nm, and energy of about 7.21 eV to about 7.75 eV.

16. The manufacturing method of the display device of claim 10, further comprising:
after the detaching of the light supply part, depositing a second organic material on the substrate through the second mask from the source supply part.

17. The manufacturing method of the display device of claim 7, wherein
the first mask includes a first blocking part and a first transmissive part,
the second mask incudes a second blocking part and a second transmissive part,
the first mask includes a first opened part formed in the first transmissive part, and
the second mask includes a second opened part formed in the second transmissive part.

18. The manufacturing method of the display device of claim 17, wherein the first mask and the second mask are disposed so that the first blocking part of the first mask overlaps the second transmissive part of the second mask and the first transmissive part of the first mask overlaps the second blocking part of the second mask.

19. The manufacturing method of the display device of claim 18, wherein
the first organic material is deposited in a deposition region corresponding to the transmissive part of the first mask among the substrate region and a peripheral area of the deposition region, and
the peripheral area of the deposition region overlaps the second transmissive part of the second mask.

20. The manufacturing method of the display device of claim 19, wherein the light dissociates chemical bonds of the selected portion of the first organic material deposited in the peripheral area of the deposition region overlapping the second transmissive part of the second mask.
